(19) United States
(12) Patent Application Publication
(10) Pub. No.: US 2009/0165857 A1
(43) Pub. Date: Jul. 2, 2009

(54) Photovoltaic Cell

(75) Inventors: Hiroto NAITO, Hitachi (JP); Naoki YOSHIMOTO, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi, Ltd.

(21) Appl. No.: 12/343,659

(22) Filed: Dec. 24, 2008

(30) Foreign Application Priority Data
Dec. 27, 2007 (JP) 2007-335518

(51) Int. Cl. H01L 31/00

(52) U.S. Cl. 136/261

(57) ABSTRACT

An organic thin-film photovoltaic cell comprises: a transparent conductor layer; a hole transport layer formed on the transparent conductor layer; a photoelectric conversion layer formed on the hole transport layer; an electron transport layer formed on the photoelectric conversion layer; and a counter electrode formed on the electron transport layer, in which: the photoelectric conversion layer is made of a mixture of a p-type semiconductor molecule or p-type polymer and an n-type semiconductor molecule; the electron transport layer contains the n-type semiconductor molecule; and the p-type semiconductor molecule or p-type polymer contained in the photoelectric conversion layer and exposed at an interface between the photoelectric conversion layer and the electron transport layer is in contact with the n-type semiconductor molecule contained in the electron transport layer.

### CLAIM OF PRIORITY

The present application claims priority from Japanese patent application serial no. 2007-335518 filed on Dec. 27, 2007, the content of which is hereby incorporated by reference into this application.

### BACKGROUND OF THE INVENTION

1. Field of the Invention

The present invention relates to bulk heterojunction organic thin-film photovoltaic cells.

2. Description of Related Art

To date, inorganic thin-film photovoltaic cells made of inorganic materials such as Si (silicon), GaAs (gallium arsenide) compounds and CuInₓGa₁₋ₓSe₂ (copper indium/gallium deselenide) compounds have been developed. However, it is difficult for these photovoltaic cells to achieve a power generation cost comparable or lower than those of conventional power generation systems (such as thermal power generation) because of their higher manufacturing cost and higher manufacturing energy cost. So, in these days, organic thin-film photovoltaic cells, which can be fabricated at low cost without the need for expensive manufacturing equipment, are being actively investigated.

Organic thin-film photovoltaic cells are broadly classified into: dye sensitized photovoltaic cells in which a dye-supporting porous TiO₂ (titanium dioxide) layer on a visible light transparent electrode is immersed in an electrolyte; schottky barrier photovoltaic cells utilizing an electricity generation mechanism provided by a schottky barrier formed between a solid organic film and a metal film; and bilayer p-n junction photovoltaic cells formed by stacking p- and n-type organic semiconductor thin-films. In some types of p-n junction photovoltaic cells, the conversion efficiency is improved by increasing the effective p-n junction area. Examples of such types of p-n junction photovoltaic cells include: photovoltaic cells fabricated by a layer-by-layer adsorption process (using a p-n junction condition that is controllable to within the order of several nanometers); and bulk heterojunction photovoltaic cells utilizing a thin-film in which a p-type organic semiconductor material (acceptor) and a n-type organic semiconductor material (donor) commingle with each other in a random mixture.

Among the above-mentioned, the dye sensitized photovoltaic cells have achieved conversion efficiencies as high as in excess of 10%; however, they use a liquid electrolyte and therefore have problems with relatively poor reliability and stability. They also have cost problems in that they need costly materials such as Ru (ruthenium) based dyes and a Pt (platinum) electrode in order to achieve high conversion efficiency (i.e., they have difficulty in achieving high conversion efficiencies with inexpensive materials). By contrast, the organic thin-film photovoltaic cells, which use solid polymer organic semiconductors, have the advantage of a low manufacturing cost because they can use inexpensive processes such as coating. Among these, bulk heterojunction organic thin-film photovoltaic cells, which use a blend of a conductive polymer and a fullerene derivative, are being actively researched and developed because they have already reached a conversion efficiency of 3% and therefore have future potential for providing a low cost and high conversion efficiency photovoltaic cell.

FIG. 5 is a schematic vertical sectional view illustrating a principal structure of a small-organic-molecule thin-film photovoltaic cell. The photovoltaic cell of FIG. 5 includes: a transparent substrate 10 made of a material such as glass; a transparent electrode 11 formed adjacent to the substrate 10; a p-type semiconductor layer 8 (e.g., copper phthalocyanine [CuPc]) formed adjacent to the electrode 11; a n-type semiconductor layer 9 (e.g., PTCBI [a perylene derivative]) formed adjacent to the semiconductor layer 8; and an electrode 12 made of a material such as Ag formed adjacent to the semiconductor layer 9. Each layer can be formed by vapor deposition or the like. In such a structure, an internal electric field is established at a p-n junction region between the p-type semiconductor layer 8 and the n-type semiconductor layer 9. Photogenerated excitons produced at the p-type semiconductor layer 8 travel to the p-n junction region where they are separated into electrons and holes by the internal electric field. The resulting electrons and holes are then transported to the opposing electrodes 12 and 11, respectively, thus generating electricity.

A problem here is that the average length the excitons can travel in the p-type semiconductor layer 8 is very short, so the thickness of the layer 8 must be made very thin according to the short diffusion length. This results in a very limited amount of light absorption (and therefore a very limited amount of carrier generation), thereby hindering achievement of high conversion efficiency.

In addition, the diffusion length of carriers in such organic thin-films is also short (generally estimated to be as short as about 100 nm at the longest). Thus, if the organic semiconductor layer 8 is made thick to absorb sufficient light, it increases the probability that generated carries (holes and electrons) recombine and disappear before they reach the electrodes 11 and 12. This adds to the difficulty in improving conversion efficiency.

There are roughly two approaches to this problem. One approach is to develop novel organic semiconductor materials which excel in such properties as mobility, carrier life and light absorptivity. However, this approach will inevitably require enormous research and development time and cost. The other is to devise methods for structurally achieving high conversion efficiency while using currently available organic semiconductor materials. One such method is to increase the effective photoelectric conversion area in such a photoelectric conversion layer.

One specific example is the above-mentioned bulk heterojunction organic thin-film photovoltaic cell. In a bulk heterojunction structure, a p-type semiconductor molecule or polymer and an n-type semiconductor molecule are mixed within a single layer and form multiple molecular level p-n junctions. Unlike planar (two-dimensional) bilayer junction structures, such bulk heterojunction structures provide multiple molecular-level p-n junctions having three-dimensional structures, thereby increasing junction area and leading to an increased photogenerated current.

Bulk heterojunction organic thin-film photovoltaic cells are divided into two types: polymer type and small molecule type. The first is a type in which a blend of a p-type organic semiconductor material (acceptor) and an n-type organic semiconductor material (donor) is dissolved in a solvent and the solution is applied by a suitable coating technique, thereby forming a thin-film having a mixture of the p- and n-semiconductors. The latter is a type in which a thin-film is formed by codepositing a p-type semiconductor and an n-type semiconductor using a vacuum vapor deposition apparatus.

FIG. 2 is a schematic vertical sectional view illustrating a principal structure of a conventional bulk heterojunction organic thin-film photovoltaic cell. Herein, the reference numeral 1 designates a transparent conductor layer, the reference numeral 2 designates a hole transport layer, the reference numeral 3 designates a hole transport layer containing a p-type semiconductor polymer or molecule, the reference numeral 4 designates an electron transport layer containing an n-type semiconductor molecule, and the reference numeral 6 designates a counter electrode. The hole transport layer 3 containing the p-type semiconductor polymer or molecule and the electron transport layer 4 containing the n-type semiconductor molecule commingle with each other in a photoelectric conversion layer 8 to form an inhomogeneous random mixture structure (bulk heterojunction structure).

In the organic thin-film photovoltaic cell of FIG. 2, the photoelectric conversion layer 8 has such a bulk heterojunction structure and the counter electrode 6 is provided on the layer 8. A problem with this structure is that the counter electrode 6 is provided to function as an electron-collecting electrode, and therefore direct contact between the counter electrode 6 and the p-type semiconductor polymer or molecule undesirably causes recombination or leakage current.

A photovoltaic cell structure currently investigated for addressing the above problem is shown in FIG. 3. FIG. 3 is a schematic vertical sectional view illustrating a principal structure of a conventional bulk heterojunction organic thin-film photovoltaic cell having a recombination (leakage current) prevention layer inserted therein. Herein, the reference numeral 1 designates a transparent conductor layer, the reference numeral 2 designates a hole transport layer, the reference numeral 3 designates a hole transport layer containing a p-type semiconductor polymer or molecule, the reference numeral 4 designates an electron transport layer containing an n-type semiconductor molecule, the reference numeral 7 designates an insulator (dielectric) layer, and the reference numeral 6 designates a counter electrode. In FIG. 3, similarly to FIG. 2, the hole transport layer 3 containing the p-type semiconductor polymer or molecule and the electron transport layer 4 containing the n-type semiconductor molecule commingle with each other in a photoelectric conversion layer 8 to form an inhomogeneous random mixture structure (bulk heterojunction structure). FIG. 3 differs from FIG. 2 in that on the FIG. 3 bulk heterojunction photoelectric conversion layer 8 a very thin insulator (dielectric) layer 7 is formed (having a thickness of several nanometers at the thickest), which provides the effect of preventing recombination (or leakage current) at the counter electrode (e.g., see JP-A-2007-88033).

However, conventional recombination (leakage current) prevention layers have a problem since they are made of an insulator or dielectric and therefore can increase the internal series resistance of a photovoltaic cell. Such an increase in internal series resistance results in degrading photoelectric conversion efficiency.

### SUMMARY OF THE INVENTION

Under these circumstances, in order to address the above problems, it is an objective of the invention to provide a bulk heterojunction organic thin-film photovoltaic cell in which recombination (leakage current) occurring between the bulk heterojunction layer and the counter electrode can be suppressed without increasing the internal series resistance.

According to one aspect of the present invention, an organic thin-film photovoltaic cell is provided, which comprises a transparent conductor layer; a hole transport layer formed on the transparent conductor layer; a photoelectric conversion layer formed on the hole transport layer; an electron transport layer formed on the photoelectric conversion layer; and a counter electrode formed on the electron transport layer, in which: the photoelectric conversion layer is made of a mixture of a p-type semiconductor molecule or p-type polymer and an n-type semiconductor molecule; the electron transport layer contains the n-type semiconductor molecule; and the p-type semiconductor molecule or p-type polymer contained in the photoelectric conversion layer and exposed at an interface between the photoelectric conversion layer and the electron transport layer is in contact with the n-type semiconductor molecule contained in the electron transport layer.

In the above aspect of the present invention, the following modifications and changes can be made.

(i) The electron transport layer has functions of blocking hole injection from a p-type semiconductor composed of the p-type semiconductor molecule into the counter electrode and preventing recombination at the counter electrode.

(ii) The valence band top level of the electron transport layer is 0.5 eV or more deeper than that of the p-type semiconductor polymer or p-type semiconductor molecule contained in the photoelectric conversion layer, with reference to the vacuum energy level.

(iii) The conduction band bottom level of the electron transport layer is less than 0.3 eV deeper than that of the n-type semiconductor molecule contained in the photoelectric conversion layer, with reference to the vacuum energy level.

(iv) The thickness of the electron transport layer is 0.1 nm or more and 50 nm or less.

(Advantages of the Invention)

The invention can provide a bulk heterojunction organic thin-film photovoltaic cell in which recombination (leakage current) occurring between the bulk heterojunction layer and the counter electrode can be suppressed without increasing the internal series resistance, thereby improving the photoelectric conversion efficiency.

### BRIEF DESCRIPTION OF THE DRAWINGS

FIG. 1 is a schematic vertical sectional view illustrating a principal structure of a photovoltaic cell according to an embodiment of the invention.

FIG. 2 is a schematic vertical sectional view illustrating a principal structure of a conventional bulk heterojunction organic thin-film photovoltaic cell.

FIG. 3 is a schematic vertical sectional view illustrating a principal structure of a conventional bulk heterojunction organic thin-film photovoltaic cell having a recombination (leakage current) prevention layer inserted therein.

FIG. 4 is schematic illustrations showing a vertical sectional view of the photovoltaic cell according to the present invention shown in FIG. 1, and showing a horizontal sectional view taken along the line A-A of the vertical sectional view.

FIG. 5 is a schematic vertical sectional view illustrating a principal structure of a conventional small-organic-molecule thin-film photovoltaic cell.

### DETAILED DESCRIPTION OF THE PREFERRED EMBODIMENTS

An embodiment of the present invention will be described below with reference to the accompanying drawings.

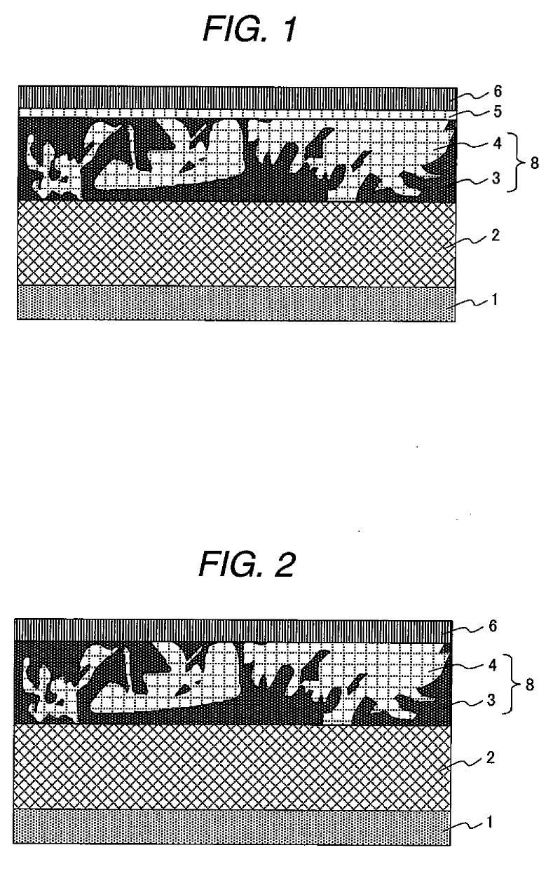

FIG. 1 is a schematic vertical sectional view illustrating a principal structure of a photovoltaic cell according to an embodiment of the invention. As shown in FIG. 1, the photovoltaic cell of the embodiment includes: a transparent conductor layer 1; a hole transport layer 2; a hole transport layer 3 containing a p-type semiconductor polymer or p-type semiconductor molecules; an electron transport layer 4 containing n-type semiconductor molecules; an electron transport layer 5 containing n-type semiconductor molecules; and a counter electrode 6. A photoelectric conversion layer 8 is formed with a mixture of the hole transport layer 3 (a p-type semiconductor containing the p-type semiconductor polymer or p-type semiconductor molecules) and the electron transport layer 4 (an n-type semiconductor containing the n-type semiconductor molecules). The p-type semiconductor polymer or each of the p-type semiconductor molecules to be the hole transport layer 3 in the photoelectric conversion layer 8 functions to absorb light and generate excitons; and each of the n-type semiconductor molecules to be the electron transport layer 4 in the photoelectric conversion layer 8 functions to transport charges. On the bulk heterojunction photoelectric conversion layer 8 are stacked the thin-film electron transport layer 5 and the counter electrode 6 in that order.

A lower part of FIG. 4 shows a vertical sectional view of the invention's photovoltaic cell which is the same as that of FIG. 1, and an upper part of FIG. 4 shows a horizontal sectional view taken along the line A-A of the vertical sectional view. As shown in FIG. 4, the p-type semiconductor (indicated by a reference number 3) composed of p-type semiconductor polymer or molecules and the n-type semiconductor (indicated by a reference number 4) composed of n-type semiconductor molecules in the photoelectric conversion layer 8 are exposed to a surface of the photoelectric conversion layer 8 (namely an interface between the photoelectric conversion layer 8 and the electron transport layer 5). Therefore, the electron transport layer 5 formed on the photoelectric conversion layer 8 is in contact with the p-type semiconductor present at the above-mentioned surface of the photoelectric conversion layer 8. The electron transport layer 5 contains its own n-type semiconductor molecules, and therefore p-n junctions are formed at portions of the interface between the photoelectric conversion layer 8 and the electron transport layer 5. Such formation of p-n junctions (between the p-type semiconductor polymer or molecules present at the surface of the photoelectric conversion layer 8 and the n-type semiconductor molecules contained in the electron transport layer 5) can increase the photogenerated current due to increased p-n junction area and can also suppress hole injection from the p-type semiconductor polymer or molecules into the counter electrode.

The transparent conductor layer 1 is preferably formed on a visible light transparent substrate. The substrate preferably has thermal stability during fabrication processing and has as low a permeability to moisture and oxygen as possible. When flexibility is not required for the substrate (namely when a rigid substrate can be used), materials that can be used for such a rigid substrate include: inorganic materials such as yttria-stabilized zirconia (YSZ) and glasses; metals such as zinc, aluminum, stainless steel, chromium, tin, nickel, iron, and copper; and ceramics. When flexibility is required, organic materials can be used such as: polyester (such as polyethylene terephthalate, polybutylene phthalate, and polyethylene naphthalate), polystyrene, polycarbonate, polyethersulfone, polyallylate, polyimide, polycycloolefin, norbornene resin, and poly (chlorotrifluoroethylene). Opaque plastic substrates can also be used. Among the above-listed organic materials, polycarbonate or the like is most typically used particularly in view of thermal resistance. Organic material that can be used for the flexible substrate preferably excels in dimensional stability, solvent resistance, electrical insulation, and workability as well as the above-mentioned thermal resistance. Use of such a flexible substrate as described above has advantages of lighter weight than ceramic substrates, enhanced flexibility, and increased resistance to bending stress.

The transparent conductor layer 1 is a visible light transparent conductive film formed by sputtering, CVD (chemical vapor deposition), sol-gel, coating-and-thermal-decomposition, etc. Materials that can be used for the transparent conductor layer 1 include indium-tin oxide (ITO), zinc oxide (ZnO), and tin oxide (SnO₂), but are not limited to them. Generally, these oxide semiconductor films are hydrophobic, so an organic semiconductor layer such as the hole transport layer 2 cannot be formed thereon without suitable treatment. To address this problem, the transparent conductor layer 1 is irradiated with UV-light for a suitable period of time in order to form hydrophilic groups at its surface, thereby facilitating the formation of an organic semiconductor layer thereon. Here, the hydrophilic group formation treatment is made to such a degree that the contact angle between the surface of the transparent conductor layer 1 and a pure water droplet on the surface is less than 10 degrees.

The hole transport layer 2 is formed on the transparent conductive layer 1 by applying a conductive polymer such as PEDOT/PSS, namely poly (3,4-ethylenedioxythiophene)/poly(styrene sulfonic acid) by method of application, spin coating or the like, and then performing a suitable after-treatment such as drying and vacuum baking.

As described above, the photoelectric conversion layer 8 is formed by an inhomogeneous random mixture of the hole transport layer 3 containing the p-type semiconductor polymer or molecules and the electron transport layer 4 containing the n-type semiconductor molecules. The mixture weight ratio of the p-type semiconductor polymer or molecules and the n-type semiconductor molecules is preferably 1:0.8, but is not limited to it. The photoelectric conversion layer 8 can be formed as follows: a desired ratio of the p-type semiconductor polymer or molecules and the n-type semiconductor molecule is dissolved in a solvent, and the solution is sufficiently stirred by ultrasonic agitation or the like. Then, the resulting solution is applied on the hole transport layer 2 by a suitable coating method such as spin coating and is subjected to an after-treatment such as drying and vacuum baking. The method for forming the photoelectric conversion layer 8 is not limited to the above-described one.

The p-type organic semiconductor molecule or the p-type semiconductor polymer as the p-type semiconductor is a donor type organic semiconductor (typified by hole transporting organic semiconductor) which has a property of readily donating electrons. Viewed somewhat differently, when two organic materials are in contact, the donor type organic semiconductor is the one having an ionization potential smaller than another and is also called as an electron-donating organic material. Therefore, any organic compounds can be used as the donor type organic semiconductor so long as it is electron donating. Exemplary materials that can be used for the donor type organic semiconductor include: triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, cyanine compounds, merocyanine compounds, oxonol compounds, polyamine compounds, indole compounds, pyrrole compounds, pyrazole compounds, polyarylene compounds, fused aromatic carbocyclic ring compounds (such as naphthalene derivatives, anthracene derivatives, phenanthrene derivatives, tetracene derivatives, pyrene derivatives, perylene derivatives, and fluoranthene derivatives), and metal complexes containing a nitrogen-containing heterocyclic compound as a ligand. Other exemplary small molecule materials that can be used for the donor type organic semiconductor include: porphyrin compounds (such as porphine, copper tetraphenylporphine, phthalocyanine, copper phthalocyanine, and titanium phthalocyanine oxide), triazole derivatives, oxathiadiazol derivatives, imidazole derivatives, polyarylalkane derivatives, pyrazoline derivatives, pyrazolone derivatives, phenylenediamine derivatives, arylamine derivatives, amino substituted chalcone derivatives, oxazole derivatives, styrylanthracene derivatives, fluorenone derivatives, hydrazone derivatives, and silazane derivatives. Other exemplary polymer materials that can be used for the donor type organic semiconductor include: polymers such as phenylenevinylene, fluorene, carbazole, indole, pyrene, pyrrole, picoline, thiophene, acetylene, and diacetylene; and derivatives of these materials. As has already been described, donor type organic semiconductors are not limited to the above-listed ones, but any organic compound having an ionization potential smaller than those of the n-type (acceptor-type) organic compounds used in the photovoltaic cell of this embodiment can be used.

The n-type organic semiconductor molecule as the n-type semiconductor is an acceptor type organic semiconductor (typified by electron transporting organic semiconductors) which has a property of readily accepting electrons. Viewed somewhat differently, when two organic materials are in contact, the acceptor type organic semiconductor is the one having an electron affinity larger than another and is also called as an electron-accepting organic material. Therefore, any organic compound can be used as the acceptor-type organic semiconductor so long as it is electron accepting. Exemplary materials that can be used for the acceptor-type organic semiconductor include: fused aromatic carbocyclic ring compounds (such as naphthalene derivatives, anthracene derivatives, phenanthrene derivatives, tetracene derivatives, pyrene derivatives, perylene derivatives, and fluoranthene derivatives); 5-7 membered heterocyclic ring compounds containing one or more heteroatoms selected from nitrogen, oxygen, and sulfur (such as pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyraridine, pyrrolopyridine, thiadiazolopyridine, dibenzazepine, and tribenzazepine); polyarylene compounds; fluorene compounds; cyclopentadiene compounds; silyl compounds; and metal complexes containing a nitrogen-containing heterocyclic compound as a ligand. Other exemplary electron accepting organic materials that can be used for the acceptor-type organic semiconductor include: fullerenes such as C60 and C70 and their derivatives; carbon nanotubes and their derivatives; oxadiazole derivatives such as 1,3-bis(4-tert-butylphenyl-1,3,4-oxadiazoyl)phenylene (OXD-7); anthraquinodimethane derivatives; diphenylquinone derivatives; bathocuproin and bathophenanthroline and their derivatives; triazole compounds; tris (8-hydroxyquinolino)aluminum complexes; bis (4-methyl-8-quinolinate)aluminum complexes; distyrylarylene derivatives; and silole compounds, but are not limited to them. As has been already described, acceptor-type organic semiconductors are not limited to the above-listed ones, but any organic compound having an electron affinity larger than that of the donor-type organic compound used in the photovoltaic cell of this embodiment can be used.

In addition, p-type organic dyes can be used as the p-type organic semiconductor, and n-type organic dyes can be used as the n-type organic semiconductor. Preferred such dyes include: cyanine dyes; styryl dyes; hemicyanine dyes; merocyanine dyes (including zero-methine merocyanine [simple merocyanine]); trinuclear merocyanine dyes; tetranuclear merocyanine dyes; rhodacyanine dyes; complex cyanine dyes; complex merocyanine dyes; allopolar dyes; oxonol dyes; hemioxonol dyes; squarium dyes; croconium dyes; azamethine dyes; coumarin dyes; allylidene dyes; anthraquinone dyes; triphenylmethane dye; azo dyes; azomethine dyes; spiro compounds; metallocene dyes; fluorenone dyes; fulgide dyes; perylene dyes; phenazine dyes; phenothiazine dyes; quinone dyes; indigo dyes; diphenylmethane dyes; polyene dyes; acridine dyes; acridinone dyes; diphenylamine dyes; quinacridone dyes; quinophthalone dyes; phenoxazine dyes; phthaloperylene dyes; porphyrin dyes; chlorophyll dyes; phthalocyanine dyes; metal complex dyes; and fused aromatic carbocyclic ring dyes (such as naphthalene derivatives, anthracene derivatives, phenanthrene derivatives, tetracene derivatives, pyrene derivatives, perylene derivatives, and fluoranthene derivatives).

The conduction band bottom level (with reference to the vacuum energy level) of the electron transport layer 5 must be deeper than that of the n-type semiconductor molecule contained in the photoelectric conversion layer 8, and the difference between the two bands is preferably less than 0.3 eV. Also, the valence band top level (with reference to the vacuum energy level) of the electron transport layer 5 must be deeper than that of the p-type semiconductor polymer or molecules contained in the photoelectric conversion layer 8, and the difference between the two bands is preferably more than 0.5 eV. Examples of such preferable materials include fullerene C60, a fullerene derivative (PCBM), and perylene derivatives, but are not limited to them. The above-listed n-type organic semiconductor molecules that can be used for the photoelectric conversion layer 8 can also be used.

These organic layers can be formed by a dry deposition method or wet deposition method. Specific examples of the dry deposition method include: physical vapor deposition (PVD) such as vacuum vapor deposition, sputtering, ion plating, and molecular beam epitaxy (MBE); and CVD such as plasma polymerization. Method of application such as cast coating, spin coating, dip coating, and the Langmuir-Blodgett (LB) technique can be used as the wet deposition method. Printing techniques such as ink-jet printing and screen printing, and transfer techniques such as thermal transfer and laser transfer can also be used. Techniques for patterning the above-mentioned organic layers include: chemical etching using photolithography or the like; physical etching using UV-light, laser light, or the like; deposition techniques (such as vacuum vapor deposition and sputtering) coupled with multiple mask sets; lift-off techniques; printing techniques; and transfer techniques.

The counter electrode 6 (metal electrode) is formed on the electron transport layer 5. The counter electrode 6 can be formed by a dry deposition method or wet deposition method. Specific examples of the dry deposition method include: PVD such as vacuum vapor deposition, sputtering, ion plating, and MBE; and CVD (chemical vapor deposition) such as plasma polymerization. Method of application such as cast coating, spin coating, dip coating, and the LB technique can be used as the wet deposition method. Printing techniques such as ink-jet printing and screen printing and transfer techniques such as thermal transfer and laser transfer can also be used. Techniques for patterning the counter electrode 6 include: chemical etching using photolithography or the like; physical etching using UV-light, laser light or the like; deposition techniques (such as vacuum vapor deposition and sputtering) coupled with multiple mask sets; lift-off techniques; printing techniques; and transfer techniques. Preferably, the metal used for the counter electrode 6 has a work function not greatly different from that of the electron transport layer 5 containing the n-type semiconductor molecule and can form an ohmic contact to the layer 5. Needles to say, care must be taken not to damage the underlying organic films (including the electron transport layer 5) during formation of the counter electrode 6.

In the thus formed organic thin-film photovoltaic cell, the light-absorbing layer (photoelectric conversion layer 8) absorbs light, is electronically excited and produces excitons. The excitons are then separated into holes and electrons by: internal electric fields formed in the p-n junction regions of the light-absorbing layer; and by a charge separating action present at both interfaces (the interface between the hole transport layer 2 and the photoelectric conversion layer 8 and the interface between the photoelectric conversion layer 8 and the electron transport layer 5). The holes travel through the hole transport layer 2 and reach a substrate electrode underlying the hole transport layer 2; therefore the substrate electrode functions as a positive electrode. The electrons travel through the electron transport layer 5 and reach the counter electrode 6; therefore the counter electrode 6 overlying the electron transport layer 5 functions as a negative electrode. The result is that a potential difference arises between the substrate and counter electrodes.

Smooth travel of the holes can be achieved by the HOMO (Highest Occupied Molecular Orbital) level gradient from the light-absorbing layer (photoelectric conversion layer 8) through the hole transport layer 2 to the substrate electrode (transparent conductor layer 1). Similarly, smooth travel of the electrons can be achieved by the LUMO (Lowest Unoccupied Molecular Orbital) level gradient from the light-absorbing layer (photoelectric conversion layer 8) through the electron transport layer 5 to the counter electrode 6. As described, the light-absorbing layer (photoelectric conversion layer 8) absorbs light and produces holes and electrons. The HOMO level gradient causes the holes to travel through the hole transport layer 2 and reach the substrate electrode (transparent conductor layer 1). Similarly, the LUMO level gradient causes the electrons to travel through the electron transport layer 5 and reach the counter electrode 6.

### FABRICATION OF EXAMPLE 1

Example 1 of the present invention will now be described by referring to FIG. 1. An ITO (indium-tin oxide) thin-film was used as the transparent conductor layer 1. The ITO film was formed on a transparent glass substrate to prepare a substrate electrode. Hereinafter, the thus prepared substrate electrode is referred to as “ITO substrate”. The ITO substrate was ultrasonically washed in acetone (for 10-15 min) and ethanol (for 10-15 min). Then, the substrate was washed in pure water or ultrapure water and dried by blowing nitrogen gas on it.

Next, the substrate was subjected to UV-ozone treatment using a UV light radiation source such as an ozone cleaner. Thereby, the substrate was given a hydrophilicity enhancing treatment, by which hydrophilic groups were formed on the surface of the ITO substrate (ITO thin-film) thus facilitating formation of an organic semiconductor layer thereon.

An aqueous solution of PEDOT/PSS was applied on the thus treated surface of the ITO thin-film by spin coating to form a hole transport layer. During spin coating, the solution was spun on at an initial spin rate of 400 rpm for 10 seconds followed by a final spin rate of 5000 rpm for 100 seconds to provide a film thickness of about 70 nm. Then, the spin coated film was heat treated in an ambient environment at an atmospheric pressure of 140° C. for 10 min, thereby completing formation of the hole transport layer.

A mixture of PCBM and P3HT was used to form a photoelectric conversion layer. The two materials were mixed to give a weight ratio of 1:1 and dissolved in o-dichlorobenzene. Subsequently, the solution was sufficiently stirred with an ultrasonic agitator and filtered through a filter having a pore size of 0.45 μm. Then, the resulting solution was applied by spin coating. During spin coating, the solution was spun on at an initial spin rate of 400 rpm for 10 seconds followed by a final spin rate of 1500 rpm for 40 seconds to provide a film thickness of about 50 nm. Then, the coated film was dried in a vacuum at room temperature, thereby obtaining a bulk heterojunction thin-film.

Next, in order to form an electron transport layer, a solution was prepared by dissolving fullerene (C60) and a polymer material such as polystyrene (PS) in o-dichlorobenzene. O-dichlorobenzene, C60, and PS were mixed to give a ratio of 217:4:1 and sufficiently stirred with an ultrasonic agitator.

The thus prepared solution was filtered through a filter having a pore size of 0.45 μm and was then applied by spin coating. During spin coating, the solution was spun on at an initial spin rate of 400 rpm for 10 seconds followed by a final spin rate of 3000 rpm for 100 seconds to provide a film thickness of 30 nm. Then, the coated film was baked in a vacuum at 100° C. for 2 h, thereby obtaining the electron transport layer.

Finally, aluminum was vacuum deposited on the electron transport layer to form an electrode. A suitable amount of aluminum wire was placed in a tungsten boat and evaporated in a vacuum of about 2×10⁻⁶ Torr at a deposition rate of 0.2-0.3 nm/s at an ambient substrate temperature and at a substrate rotation rate of 30 rpm to form a 50-nm-thick aluminum thin-film.

### FABRICATION OF EXAMPLE 2

Example 2 differed from Example 1 in that a 0.5-nm-thick sublimation-purified fullerene (C60) was vacuum vapor deposited as the electron transport layer (between the photoelectric conversion layer and the counter electrode). The other steps for fabricating the Example 2 organic thin-film photovoltaic cell were similar to those used in Example 1. The valence band top level (with reference to the vacuum energy level) of the sublimation-purified fullerene is deeper (by more than 0.5 eV) than that of the p-type semiconductor polymer or p-type semiconductor molecules in the photoelectric conversion layer used in this example. In addition, the conduction band bottom level of the sublimation-purified fullerene is deeper (by less than 0.3 eV) than that of the n-type semiconductor molecules in the photoelectric conversion layer used in this example.

### FABRICATION OF COMPARATIVE EXAMPLE 1

Comparative Example 1 differed from Example 1 only in that the electrode was formed directly on the photoelectric conversion layer and therefore the electron transport layer 5 was not provided.

### FABRICATION OF COMPARATIVE EXAMPLE 2

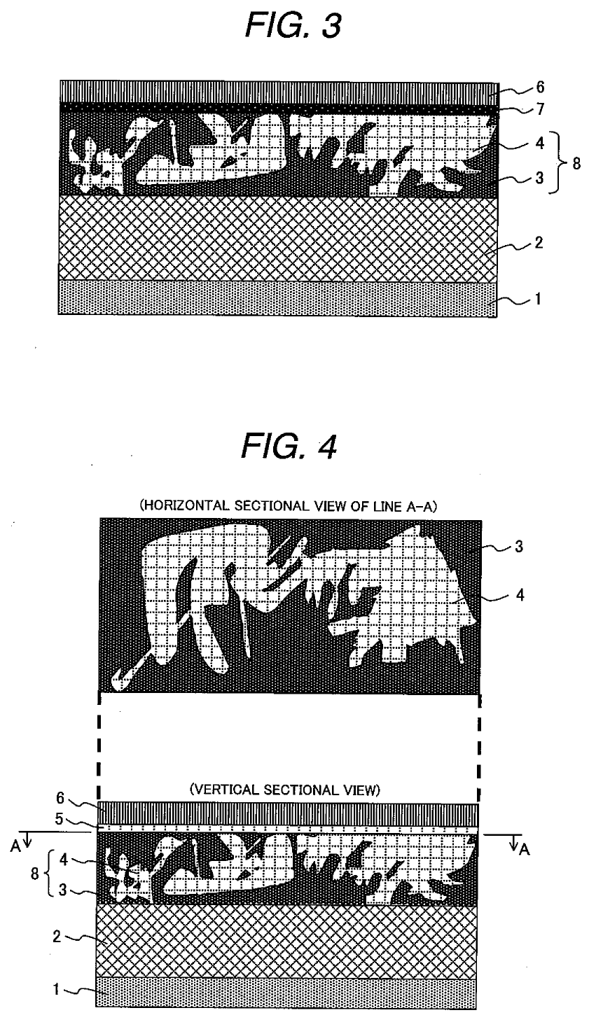

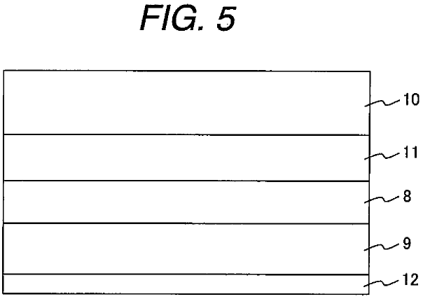

Comparative Example 2 differed from Example 1 only in that a 1-nm-thick LiF (lithium fluoride) dielectric layer such as shown in FIG. 3 was used instead of the electron transport layer 5.

### FABRICATION OF COMPARATIVE EXAMPLE 3

Comparative Example 3 differed from Comparative Example 2 only in that the thickness of the dielectric layer was 10 nm.

### FABRICATION OF COMPARATIVE EXAMPLE 4

Comparative Example 4 differed from Example 1 only in that the thickness of the electron transport layer (between the photoelectric conversion layer and the counter electrode) was 100 nm.

(Output Characteristics of Organic Thin-Film Photovoltaic Cell)

The thus fabricated bulk heterojunction organic thin-film photovoltaic cells (Examples 1-2 and Comparative Examples 1-4) were irradiated with a simulated solar irradiation of AM 1.5 using a solar simulator and were measured and evaluated for their output characteristics. The results are shown in Tables 1 and 2.

TABLE 1

| | Example 1 | Example 2 |
|---|---|---|
| Short-Circuit Current | 3.0 | 2.7 |
| (mA/cm²) | | |
| Open-Circuit Voltage | 0.50 | 0.49 |
| (V) | | |
| Fill Factor | 0.45 | 0.51 |
| Conversion Efficiency | 0.675 | 0.674 |
| (%) | | |

TABLE 2

| | | Compar- | Compar- | Compar- |
|---|---|---|---|---|
| | Comparative | ative | ative | ative |
| | Example 1 | Example 2 | Example 3 | Example 4 |
| Short-Circuit Current | 1.3 | 1.1 | 0.3 | 1.0 |
| (mA/cm²) | | | | |
| Open-Circuit Voltage | 0.4 | 0.47 | 0.38 | 0.38 |
| (V) | | | | |
| Fill Factor | 0.31 | 0.53 | 0.27 | 0.28 |
| Conversion Efficiency | 0.161 | 0.274 | 0.030 | 0.106 |
| (%) | | | | |

As can be seen from Tables 1 and 2, the organic thin-film photovoltaic cells according to the present invention exhibit an improved short-circuit current, thus leading to improved conversion efficiency. Comparison of Example 1 with Comparative Example 1 shows that provision of the electron transport layer of the invention increases the photogenerated charge by an increased p-n junction area, thereby improving the short-circuit current. Also, the fill factor of Example 1 is improved compared to that of Comparative Example 1, probably indicating that the leakage current is suppressed.

The result for Example 2 shows that use of a material having proper valence and conduction band levels for the electron transport layer can suppress hole injection to the counter electrode as well as recombination at the counter electrode, thereby leading to an improved fill factor. The result for Comparative Example 2 shows that insertion of a thin LiF layer as a hole blocking layer can suppress hole injection to the counter electrode, but can have little contribution to increasing the photogenerated current.

The results for Comparative Examples 3 and 4, which have a thicker hole blocking layer than Comparative Example 2 and Example 2 respectively, show that the thicker the hole blocking layer is, the poorer the fill factor is and the less the short-circuit current is. This is probably because such a thick hole blocking layer has an adverse effect of adding to the internal series resistance of the photovoltaic cell.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. An organic thin-film photovoltaic cell, comprising:
a transparent conductor layer;
a hole transport layer formed on the transparent conductor layer;
a photoelectric conversion layer formed on the hole transport layer;
an electron transport layer formed on the photoelectric conversion layer; and
a counter electrode formed on the electron transport layer, wherein:
the photoelectric conversion layer is made of a mixture of a p-type semiconductor molecule or p-type polymer and an n-type semiconductor molecule; the electron transport layer contains the n-type semiconductor molecule; and the p-type semiconductor molecule or p-type polymer contained in the photoelectric conversion layer and exposed at an interface between the photoelectric conversion layer and the electron transport layer is in contact with the n-type semiconductor molecule contained in the electron transport layer.

2. The organic thin-film photovoltaic cell according to claim 1, wherein:
the electron transport layer has functions of blocking hole injection from a p-type semiconductor composed of the p-type semiconductor molecule into the counter electrode and preventing recombination at the counter electrode.

3. The organic thin-film photovoltaic cell according to claim 1, wherein:
the valence band level of the electron transport layer is 0.5 eV or more deeper than that of the p-type semiconductor polymer or p-type semiconductor molecule contained in the photoelectric conversion layer, with reference to the vacuum energy level.

4. The organic thin-film photovoltaic cell according to claim 1, wherein:
the conduction band level of the electron transport layer is less than 0.3 eV deeper than that of the n-type semiconductor molecule contained in the photoelectric conversion layer, with reference to the vacuum energy level.

5. The organic thin-film photovoltaic cell according to claim 3, wherein:
the conduction band level of the electron transport layer is less than 0.3 eV deeper than that of the n-type semiconductor molecule contained in the photoelectric conversion layer, with reference to the vacuum energy level.

6. The organic thin-film photovoltaic cell according to claim 1, wherein:
the thickness of the electron transport layer is 0.1 nm or more and 50 nm or less.
